(19) United States
(12) Patent Application Publication
(10) Pub. No.: US 2017/0082687 A1
(43) Pub. Date: Mar. 23, 2017

(54) DE-BUGGING ENVIRONMENT WITH SMART CARD

(71) Applicants: ROLAND W. KLINGER, Merrimack, NH (US); DIRK F. BLEVINS, Russell Springs, KY (US); JOHN M. MORGAN, Townsend, MA (US); ERIC D. HEATON, San Francisco, CA (US); AI BEE LIM, Oakham, MA (US); LIANG-MIN WANG, Northborough, MA (US)

(72) Inventors: ROLAND W. KLINGER, Merrimack, NH (US); DIRK F. BLEVINS, Russell Springs, KY (US); JOHN M. MORGAN, Townsend, MA (US); ERIC D. HEATON, San Francisco, CA (US); AI BEE LIM, Oakham, MA (US); LIANG-MIN WANG, Northborough, MA (US)

(21) Appl. No.: 14/862,964

(22) Filed: Sep. 23, 2015

(51) Int. Cl. G01R 31/3177; G01R 31/317

(52) U.S. Cl. CPC G01R 31/3177; G01R 31/31702

(57) ABSTRACT

A method performed on a user interface device is described. The method includes connecting to a smart card where the smart card is connected to an electronic system to be de-bugged. The method also includes causing a cloud service to download customized test vectors for the electronic system to the smart card. The method also includes causing the smart card to begin execution of test software and/or operation of programmable hardware logic circuitry that uses the customized test vectors to test the electronic system.

### FIELD OF INVENTION

The field of invention pertains generally to the electronic arts, and, more specifically, to a de-bugging environment with a smart card.

### BACKGROUND

Electronic system de-bugging has traditionally been a cumbersome, manual process in which engineers mount test probes on hardware under development and compare the actual, measured electronic signals against their designed for data levels, waveforms, timings, etc. In the case where numerous signals need to be measured in approximately the same time frame the measurement process can be especially cumbersome because a large number of probes need to be in place and their corresponding signals need to be concurrently tracked by expensive test equipment.

### FIGURES

A better understanding of the present invention can be obtained from the following detailed description in conjunction with the following drawings, in which:

FIG. 1 shows a system-on-chip with multiple reset signals;

FIG. 2a shows a testing environment;

FIG. 2b shows a method performed by a smart card of the testing environment;

FIG. 3 shows an embodiment of a smart card;

FIG. 4 shows analog samples displayed against an analog test vector;

FIG. 5 shows another methodology performed by a smart card of the testing environment;

FIG. 6 shows icons that may be displayed by a user interface device that is communicatively coupled with the smart card;

FIG. 7 shows a computing system.

### DETAILED DESCRIPTION

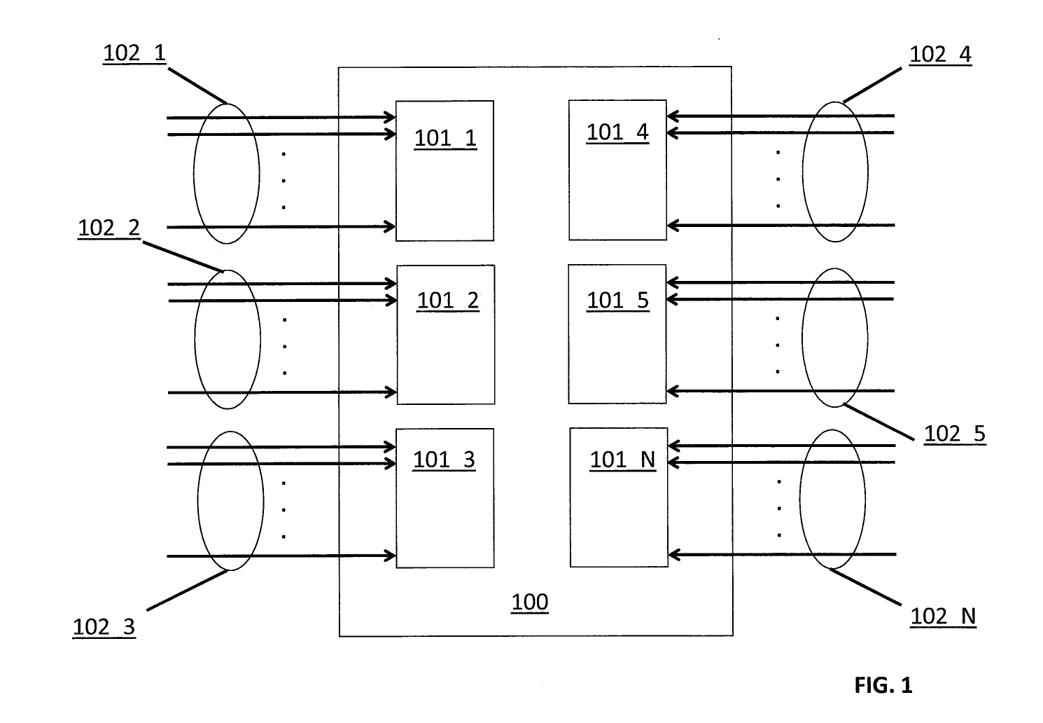

The power-on-reset activity of a system-on-chip is one potential difficult debugging environment. As observed in FIG. 1, a system-on-chip 100 may consist of a number of legacy logic designs 101_1 through 101_N that were, e.g., originally designed for separate semiconductor chips but are now integrated on a same semiconductor chip or within a same package as, e.g., a multi-chip module.

In many cases the legacy designs were originally designed with their own unique set of bring-up/reset signals 102_1 through 102_N that have been preserved in the larger system-on-chip 100. As such, the system-on-chip 100 includes a large number of different sets of reset signals 102_1 through 102_N which may include relative to one another, e.g., different types of reset signals, different reset timing conditions and/or different reset signal voltage levels. In order for the system-on-chip 100 to power-on and/or come out of reset properly, ideally, all of the reset signal sets 102_1 through 102_N are within their specific specifications. During de-bug testing of the actual system on chip 100, verifying that all the reset signals are correct can be an extremely burdensome process.

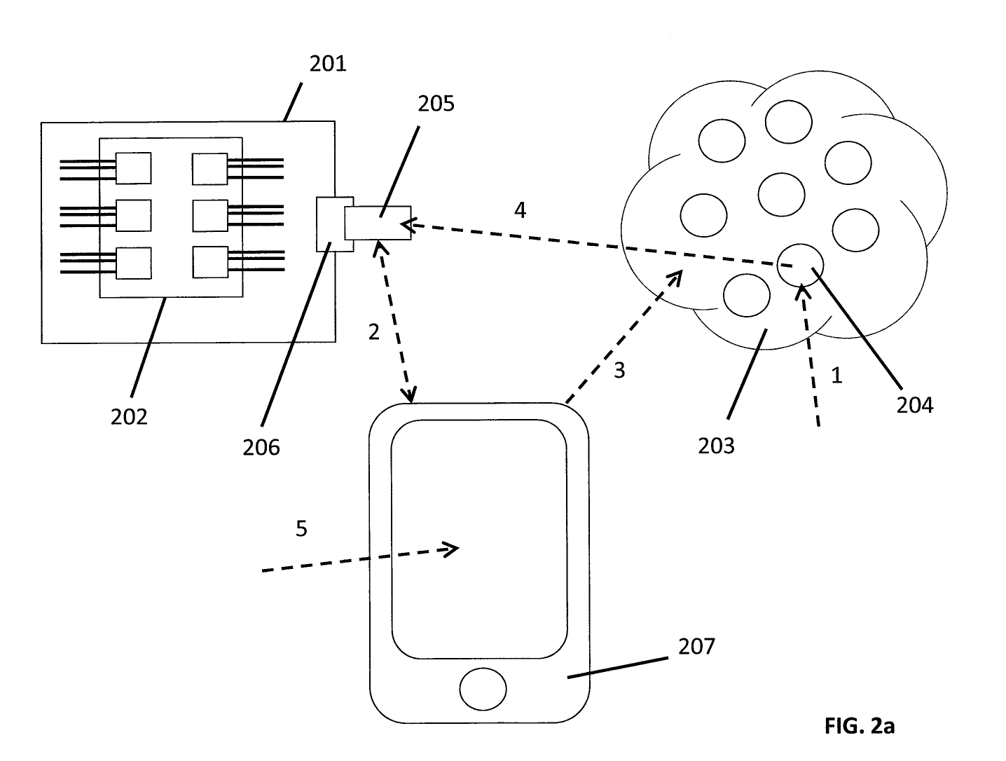

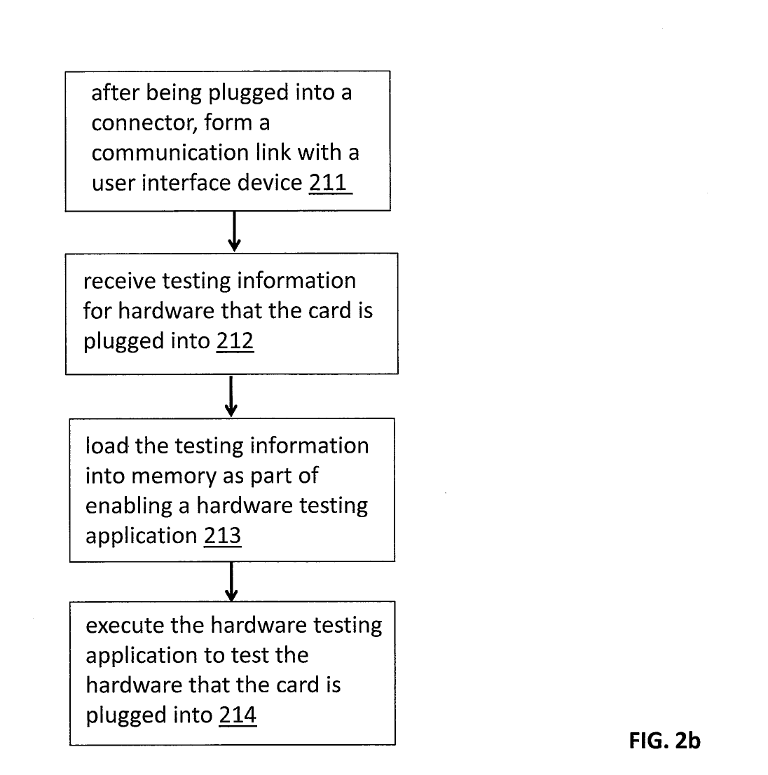

FIG. 2a shows a test and de-bug environment that greatly simplifies the testing of hardware under test, such as the testing of the reset signaling for a large system-on-chip. An example may include a planar board (or “PC” board) for a computing system having one or more multiple general purpose processing core system-on-chips. Here, as discussed above with respect to FIG. 1, the processor system-on-chip may have a complicated set of reset signals owing to its inclusion of multiple legacy designs.

As observed in FIG. 2, as just one example, the PC board 201 includes a system-on-chip 202 with different sets of reset input signals as discussed with respect to FIG. 1. In an embodiment, designers of the PC board or the manufacturer of the system on chip 201 upload 1 to a cloud service 203 an application software program 204 (and/or test vectors or rules for an application software program) that is custom designed to test critical signals of the specific PC board 201 being designed and/or the system-on-chip 202 that is part of the PC board 201.

As an example, the application software program 204 may be designed to monitor/test multiple ones of the system-on-chip's various reset signal lines (e.g., all of them). In various embodiments, the application software program 204 is also designed to generate critical input stimuli to the PC board 201, such as an on/off signal and/or one or more system reset signals.

A “smart card” 205 removably plugs-into a connector 206 that is mounted to the PC board 201. The smart card 205, in various embodiments is a small form factor electronic system (e.g., composed of one or more semiconductor chips disposed on its own respective PC board). The smart card 205 has a network interface that allows the card to communicate over a network with the cloud service 204. The smart card 205 also has a point-to-point link interface (e.g., Universal Serial Bus, Bluetooth) that permits the smart card to communicate 2 with a user interface device 207 (e.g., a smartphone, tablet computer, laptop computer, desktop computer, etc.).

The user interface device 207 presents a graphical user interface that a user interfaces with in order to control the smart card 205 and its software. In an embodiment, through the user interface device 207 interface, a user causes 3 the application software 204 that has been written for the PC board and/or system-on-chip 202 to be downloaded 4 from the cloud service 203 and loaded onto the smart card 205.

The user, through 5 the user interface device 207, causes the smart card 205 to begin execution of the application software and its custom testing of the hardware being de-bugged. Via the aforementioned input stimuli signals provided by the smart card 205, in various embodiments, the smart card 205 can turn the PC board 201 on/off and/or reset the PC board 201 through the connector 206. Additionally, various critical signals of the PC board 201, such as multiple ones of the sets of reset signals that are applied to the system-on-chip 202 are also routed to the connector 206 so the signals on these same signal lines can be received and monitored by the smart card 205.

As the PC board 201 begins operation (e.g., during a system power-on-reset sequence), the various signal lines of the PC board 201 that have been tapped to also run as input signals to the connector 206 are received by the smart card 205 and are monitored/tested by the smart card 205 according to the routines executed by the application software program 204.

In an embodiment, the application software 204 includes test vectors that describe each of the signals as they should exist over time. The actually received signals are time-stamped and compared against test vectors with corresponding timestamp and any signals that do not match the test vector data are flagged as a problem and reported to the user interface device 207 which informs the user through its display. As such, the design engineers are immediately informed of a specific problem and its details without having to set-up test probes or manually setup testing equipment to individually track each of the signals being monitored.

FIG. 2b shows a methodology that can be performed by a smart card as described above. As observed in FIG. 2b, the method includes, after being plugged into a connector, form a communication link with a user interface device 211. The method also includes receiving testing information for hardware that the card is plugged into 212. The method also includes loading the testing information into memory as part of enabling a hardware testing application 213. The method also includes executing the hardware testing application to test the hardware that the card is plugged into 214.

FIGS. 2a and 2b were directed to an embodiment in which the test engineers develop, and the smart card executes, a customized software test application for the system being debugged. In an alternate or combined approach, the test engineers may generate a custom hardware logic description (e.g., an RTL description) for programmable hardware logic circuitry (such as a programmable logic device (PLD) or field programmable gate array (FPGA)) that is uploaded to the cloud service and downloaded to the smart card. Upon receipt of the custom hardware description (e.g., into memory of the smart card), the custom hardware description is then used to program programmable hardware logic circuitry on the smart card so that the programmable hardware logic circuitry can perform customized test logic operations (such as comparing sampled data against test vectors) for the system being de-bugged. For simplicity, the remainder of the specification will refer mainly to test application software. However, the reader should understand that much of the discussion below can also pertain to approaches that embrace programmable hardware logic circuitry for customized testing by itself or along with customized test software.

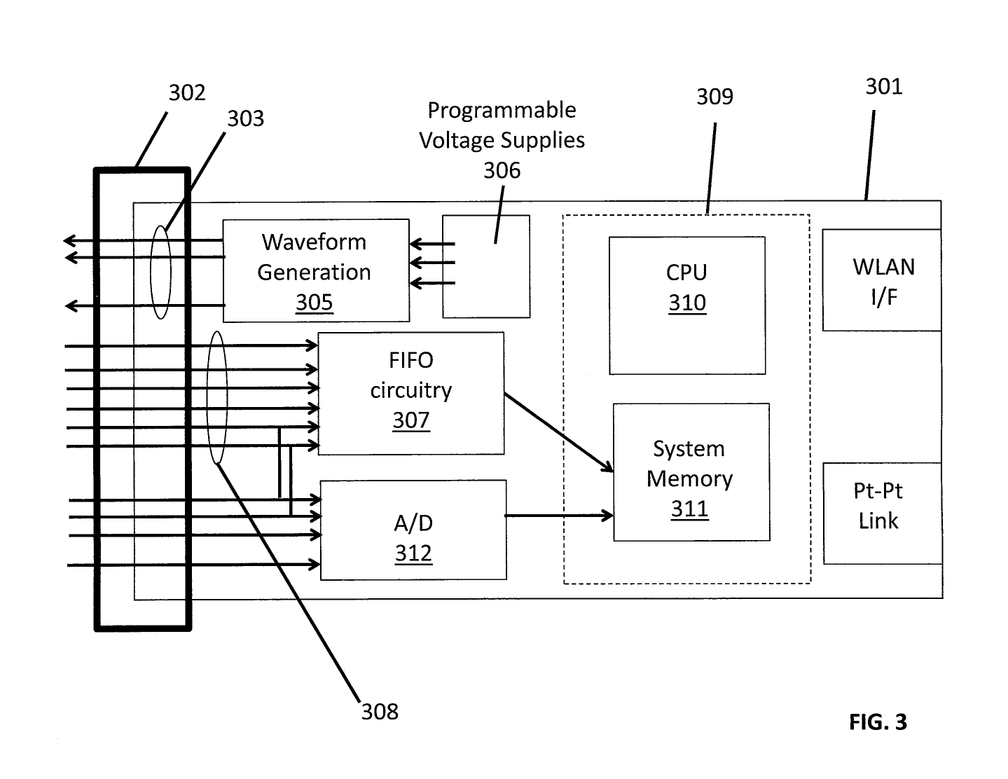

FIG. 3 shows a design of a smart card 301. As observed in FIG. 3, the smart card 301 includes a connector 302 that connects to a compatible mating connector (not shown) that, e.g., may be mounted to a PC board. As described above, the connector 302 has output signal lines 303 to generate input stimuli to the hardware being de-bugged. From the smart card perspective, in an embodiment, the output signal lines 303 are generic output signal lines that can generate any type of input signal to the hardware being de-bugged. Here, for instance, programmable waveform generation logic circuitry 305 may craft any digital signal in terms of its pulse width, pulse shape, when a rise time starts, when a fall time falls, fundamental frequency, etc. The programmable waveform generation logic circuitry 305 may further include one or more phase-locked-loop circuits to generate any of these signals and/or provide a clock signal as an output stimuli.

In further embodiments, the waveform generation logic circuitry 305 may be further capable of receiving different power supply voltages so that the generated digital input stimuli also have programmably adjustable voltage levels. Here, in an embodiment, the smart card 301 also includes multiple programmable voltage supplies 306 to provide the waveform generation logic circuitry 305 with any of one or more different supply voltages so that input stimuli provided to the hardware under test can be provided with different logic voltage levels. For instance, as just one example, a digital signal can be provided with any of the following logic high voltage levels: 3.3v, 1.8v or 1.05v.

In a further embodiment, the smart card 301 includes FIFO circuitry 307 for fast capturing of digital signals. Here, for instance, the set of logic signals 308 being directed from the hardware being debugged to the smart card 301 can be viewed as different states of the hardware. If all of the logic signals are generated from a single clock source, each clock cycle may correspond to a new state that the FIFO circuitry 307 captures. Note that the clock signal itself may be directed to and received by the smart card and FIFO circuitry 307 so that the FIFO circuitry 307 can capture the new state information with each clock cycle.

In an embodiment, the FIFO circuitry 307 includes an associated state machine circuit that controls input sample capture to the FIFO circuitry 307 which, in turn, gives the smart card 301 some testing flexibility. For example, the state machine may be programmed with a trigger value (e.g., a specific number of clock cycles after a power on signal, a reset signal, an observed system state, etc.) and/or digital sample collection approach (collect samples on detected data change of any of the samples, collect samples on each input clock edge, etc.).

The aforementioned FIFO circuitry may be instantiated multiple times. That is, e.g., different FIFO circuits may be able to receive different sets of signals generated from different clocks where each FIFO circuit receives a particular set of signals generated from a particular clock. In this manner, state information that is generated according to different timing parameters may be fully captured by the smart card in a synchronous fashion. The FIFO circuitry 307 (and any state machine circuitry) may be implemented with one or more semiconductor chips such as a programmable logic device (PLD), field programmable gate array (FPGA) or custom designed logic circuit.

Upon collection of the state information generated by the hardware the FIFO circuitry 307 proceeds to forward the collected state information to a CPU complex 309 that includes a processor 310 and system memory 311. The collected state information that is forwarded to the CPU complex 309 is loaded into the system memory 311. In an embodiment, the custom testing application software that has been downloaded and is executing operates out of the same system memory 311. That is, the application software is loaded into the same system memory 311 that the FIFO captured state information is loaded into.

The processor 310 executes the program code and refers to the FIFO captured state information as input data. In an embodiment, as mentioned above, the application software includes or otherwise refers to previously generated test vector data that the captured data from the FIFO circuitry 307 is compared against. For the digitally collected state information from the FIFO circuitry 307, the test vectors take the form of a set of 1 s and 0s (one 0 or 1 for each signal in the vector). The application software during execution continually compares the measured sets of collected FIFO data against their corresponding test vectors. When a captured set of FIFO data does not match its particular test vector an error flag is raised by the application software and reported to the user interface device. As mentioned previously, both the test vectors and the sampled FIFO data may be time-stamped (e.g., on a relative basis) so the correct vector is compared against the correct sampled data.

As mentioned above, it is pertinent to recognize that the functionality of the CPU complex may instead be implemented with programmable hardware logic circuitry that is programmed in a customized fashion to perform the testing operations in hardware rather than software. In other possible embodiments, a CPU complex may co-exist with programmable hardware logic circuitry so that some elements of testing are performed with customized software on the CPU complex while other elements of the testing are performed in hardware customized programmed hardware logic circuitry.

The smart card 301 also includes a plurality of analog-to-digital converters 312. The plurality of analog-to-digital converters 312 can receive input signals directly from the connector 302, and/or, from one or more signals that are also sent to the FIFO circuitry 307. In the case of the later, where a same signal is routed to both the FIFO circuitry 307 and an analog-to-digital converter 312, the smart card 301 is able to not only measure the signal's logic state (with the FIFO circuitry 307) but also measure the signal's waveform shape (with the analog-to-digital circuitry 312).

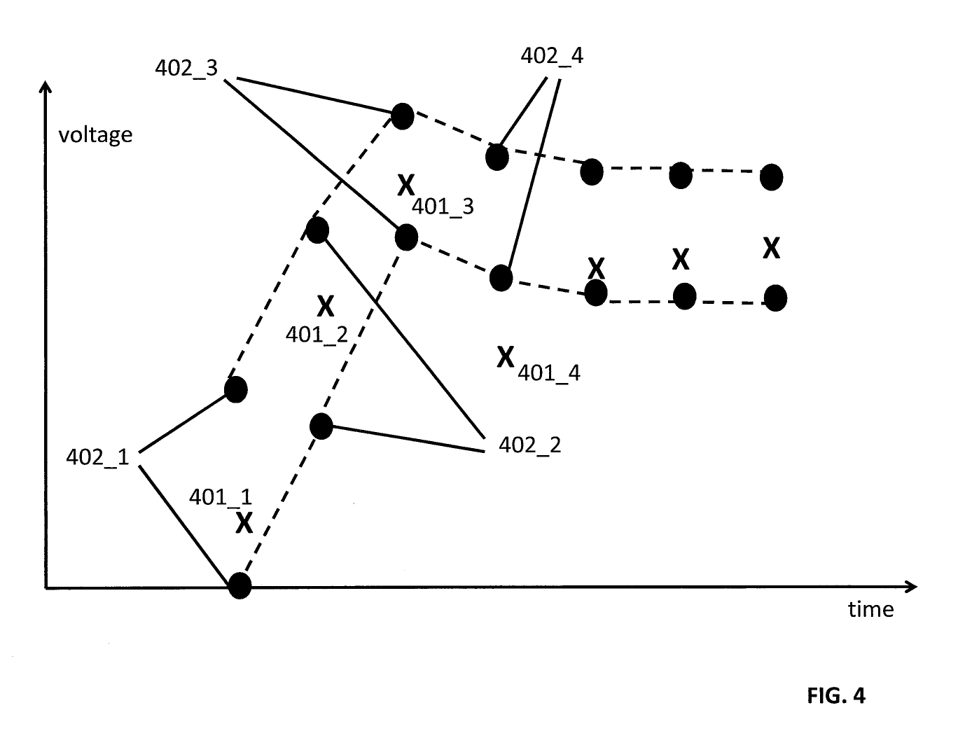

In operation, as observed in FIG. 4, an analog-to-digital converter circuit collects digital samples 401 of the voltage level of a specific signal from the hardware being de-bugged and loads the samples into the system memory of the CPU complex. The application software also includes test vectors 402 for the analog measured signal. The test vectors 402 for the analog measured signals are implemented as a series of digital samples where each sample corresponds to a different moment in time and defines a voltage range within which the measured signal 401 is supposed to remain within.

Here, referring to FIG. 4, the collected samples 401 from an analog-to-digital converter are displayed against a pair of values of the corresponding test vector 402 across time. Note that the pair of values of the test vector 402 map out a “profile” within which the measured analog signal 401 is expected to fit within. If a sample falls outside the profile, such as sample 401_4, an error is flagged and reported to the user interface device.

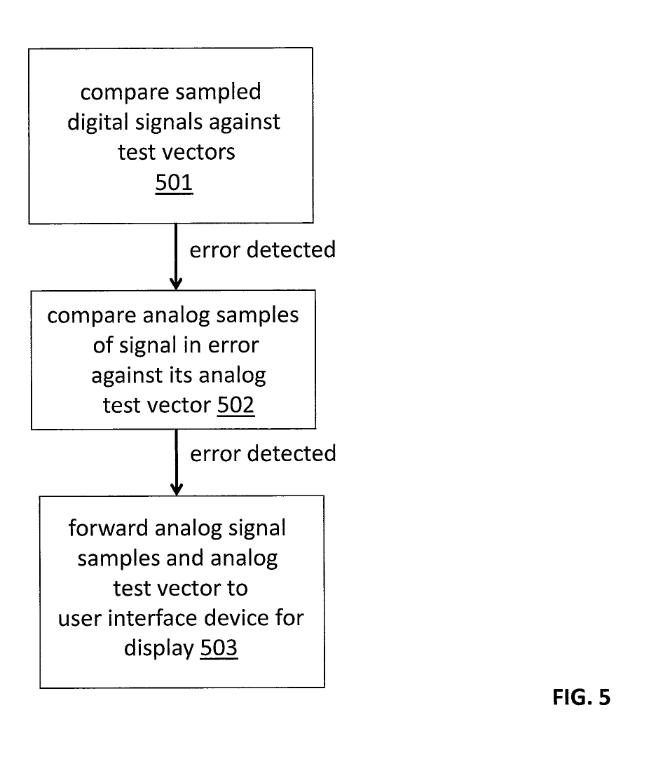

FIG. 5 shows a test and debug process that can be executed by the smart card that captures a signal both digitally and with analog-to-digital converters. As observed in the methodology of FIG. 5, the smart card initially compares digital sets of signals (e.g., as state information of the hardware being debugged) against pre-established test vectors that are referred to by the application software program 501. If the application test program flags an error with one of the signals in a test vector the application test program looks to see if the same signal that was flagged was also being monitored with analog-to-digital conversion circuitry.

If the signal was also being monitored with analog-to-digital circuitry of the smart card, the application software next compares 502 the digital samples of the signal taken by the analog-to-digital circuitry against the test vector information for the analog signal. In an embodiment, as discussed above, both the digital samples and the analog samples are time-stamped by the measurement devices (e.g., the FIFO circuitry in the case of the digital samples and the analog-to-digital converters in the case of the analog samples) so that they can be properly aligned in time

If the actually measured signal falls outside its specified profile as defined by the analog test vector, an error is flagged. The error is reported 503 to the user interface device along with the analog samples and the analog test vector information. The user interface device is then able to plot on its display the measured waveform against the profile similar to the depiction observed in FIG. 4. In view of this information, an engineer will have an automatically generated snapshot of a signal glitch that may have caused the incorrect digital value representation during the digital comparison 501. The temporal location and/or voltage level of the glitch, as observed on the user interface device, may immediately provide the engineer with clues as to the root cause of the problem.

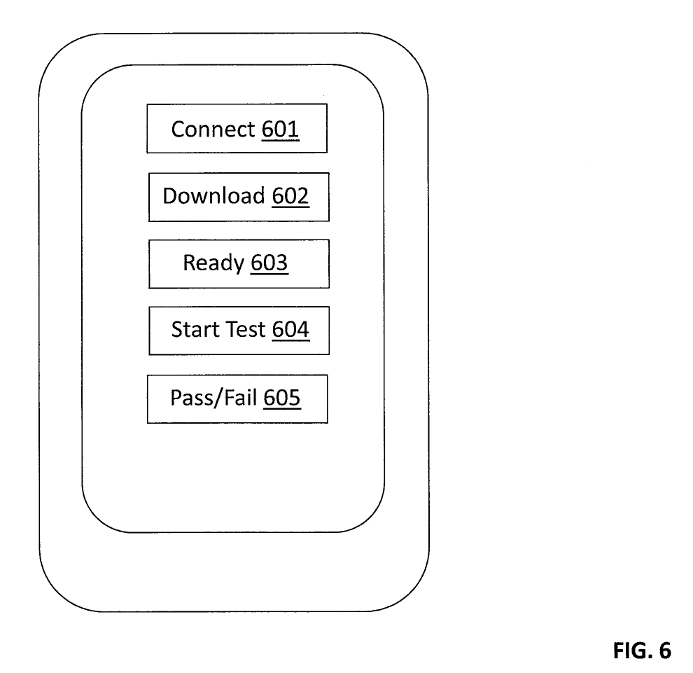

FIG. 6 shows some of the types of menu commands that may be presented on the display of the user interface device to enable a smart card as described above to automatically test a hardware circuit being debugged. As observed in FIG. 6, the display may present a connect icon 601 to connect to a smart card (e.g., that is proximately located to).

The display may also present a download icon 602 to download a particular software application to the smart card. In an embodiment, as part of the download process, the engineer initially has to “log-in” with the cloud service (e.g., with a unique user ID and password). The cloud service sends a message and data to the user interface device that causes the user interface device to display a list of application software programs that have been loaded into and registered with the cloud service for the user's account.

The user then selects one of the application software programs and, in response, the cloud service downloads the application software program to the smart card that the user interface device is communicatively coupled to. As part of the download procedure, the user interface device may identify the network address of the smart card to the cloud service, or, the user interface device may cause the smart card to identify itself to the cloud service. The display of the user interface device may also show download status (e.g., % complete, download complete, etc.) based on information sent from the smart card to the user interface device during the actual downloading.

Note that the test application software may be provided by a manufacturer of the device being tested. For example, continuing with the example above where the testing application software is to test the power-on-reset signaling of a large system on chip, the application test software may be provided by the manufacturer of the system of chip as a testing tool for their own product. Customers of the system-on-chip may order the testing application software from the chip manufacturer. The chip manufacturer uploads the application test software to the cloud service.

The display may also present an indication to the user that the application software has been properly loaded and is ready to execute 603. Again the smart card may communicate this information to the user interface device. After the user has been informed that the software is ready to execute the display may present a “start test” icon 604 to the user. In response to touching the start test icon, the user interface device sends a start test command to the smart card and the smart card causes the application software program to begin execution. The display may also indicate whether the test run by the application software has passed 605, or, if not, provide an indication of failure and any follow on information that could help isolate the problem (such as a particular signal line at a particular moment of time).

Referring briefly back to FIG. 1, note that the same connector may be mounted on many different hardware systems being de-bugged. Additionally, one or more of the smart cards may be available for use. Here, any smart card can plug into any of the different hardware systems being de-bugged and, because of its generic design and just-in-time download of test application software, the smart card can be used to successfully de-bug the card.

In various embodiments, the application test software is generically written and is a part of the firmware of the smart card. The aforementioned application software program that is loaded from the cloud service is, instead of being an entire application test program, is just a record of the input stimuli to be applied and/or the test vectors against which the measured samples are compared. Various other embodiments between these two extremes are possible (e.g., some custom test execution code may be part of the test sequence information that is downloaded from the cloud service while other parts of the testing software may be generic and part of the smart card firmware).

Note that although embodiments described above were directed to hardware de-bugging, the de-bugging environment described at length could also be used to de-bug software/firmware, or software and hardware combined. Here, as is understood in the art, software/firmware often directs hardware to take certain actions that are detectible on the hardware's signal lines, and/or, responds to stimuli that are detectible on the hardware's signal lines.

Note that although embodiments above are directed to embodiments where the test application software is received through a first communication interface and the smart card communicates with the user interface device through a second communication interface, in various other embodiments, the test vectors may be received and communication with the user interface device may take place through a same communication interface.

Note that although the above examples have emphasized the de-bugging of reset signals supplied to a system-on-chip, the approach above can theoretically be applied to any hardware system and system of signal lines for which monitoring is desired. Examples include system interface bus lines (e.g., peripheral bus interfaces, memory interfaces, communication interfaces, etc.) various control lines and power supply rails. Essentially, signal lines between any component with a system, such as a computing system, may be tested as described above.

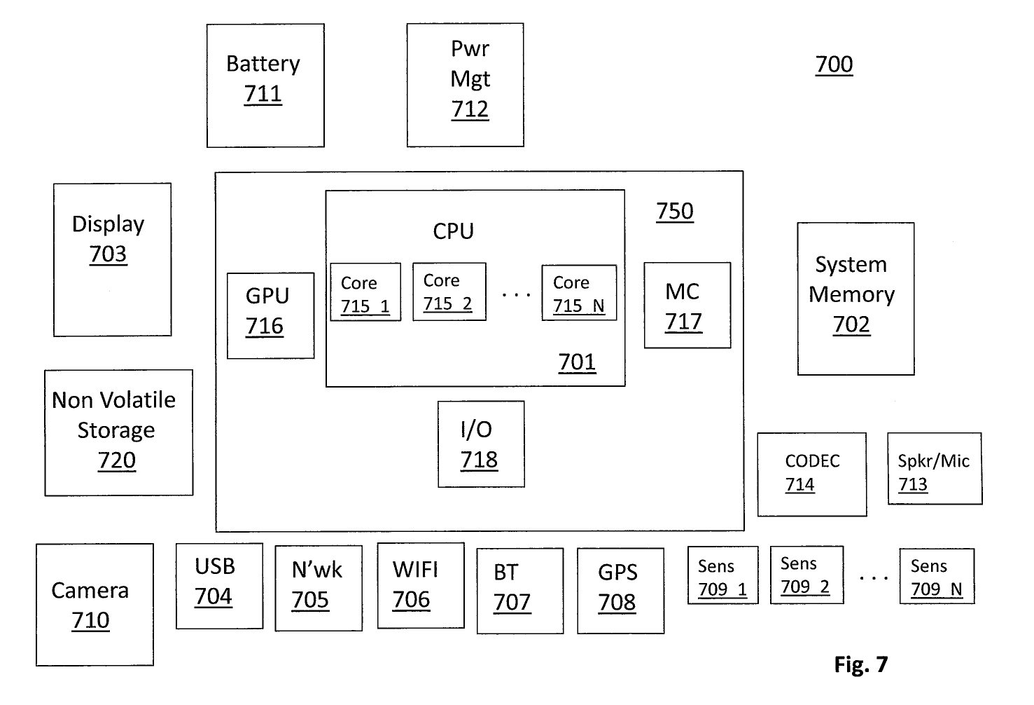

FIG. 7 shows a depiction of an exemplary computing system 700 such as a personal computing system (e.g., desktop or laptop) or a mobile or handheld computing system such as a tablet device or smartphone, or, a larger computing system such as a server computing system any one of which may be a system that the testing system described herein is configured to test. FIG. 7 may describe the system being de-bugged and/or the device that communicates with the smart card.

As observed in FIG. 7, the basic computing system may include a central processing unit 701 (which may include, e.g., a plurality of general purpose processing cores and a main memory controller disposed on an applications processor or multi-core processor), system memory 702, a display 703 (e.g., touchscreen, flat-panel), a local wired point-to-point link (e.g., USB) interface 704, various network I/O functions 705 (such as an Ethernet interface and/or cellular modem subsystem), a wireless local area network (e.g., WiFi) interface 706, a wireless point-to-point link (e.g., Bluetooth) interface 707 and a Global Positioning System interface 708, various sensors 709_1 through 709_N (e.g., one or more of a gyroscope, an accelerometer, a magnetometer, a temperature sensor, a pressure sensor, a humidity sensor, etc.), a camera 710, a battery 711, a power management control unit 712, a speaker and microphone 713 and an audio coder/decoder 714.

An applications processor or multi-core processor 750 may include one or more general purpose processing cores 715 within its CPU 701, one or more graphical processing units 716, a memory management function 717 (e.g., a memory controller) and an I/O control function 718. The general purpose processing cores 715 typically execute the operating system and application software of the computing system. The graphics processing units 716 typically execute graphics intensive functions to, e.g., generate graphics information that is presented on the display 703. The memory control function 717 interfaces with the system memory 702. The system memory 702 may be a multi-level system memory such as the multi-level system memory discussed at length above. The memory controller may include a pinning engine as described above. During operation, data and/or instructions are typically transferred between deeper non volatile (e.g., “disk”) storage 720 and system memory 702. The power management control unit 712 generally controls the power consumption of the system 700.

Each of the touchscreen display 703, the communication interfaces 704-707, the GPS interface 708, the sensors 709, the camera 710, and the speaker/microphone codec 713, 714 all can be viewed as various forms of I/O (input and/or output) relative to the overall computing system including, where appropriate, an integrated peripheral device as well (e.g., the camera 710). Depending on implementation, various ones of these I/O components may be integrated on the applications processor/multi-core processor 750 or may be located off the die or outside the package of the applications processor/multi-core processor 750.

Embodiments of the invention may include various processes as set forth above. The processes may be embodied in machine-executable instructions. The instructions can be used to cause a general-purpose or special-purpose processor to perform certain processes. Alternatively, these processes may be performed by specific hardware components that contain hardwired logic for performing the processes, or by any combination of programmed computer components and custom hardware components.

Elements of the present invention may also be provided as a machine-readable medium for storing the machine-executable instructions. The machine-readable medium may include, but is not limited to, floppy diskettes, optical disks, CD-ROMs, and magneto-optical disks, FLASH memory, ROMs, RAMs, EPROMs, EEPROMs, magnetic or optical cards, propagation media or other type of media/machine-readable medium suitable for storing electronic instructions. For example, the present invention may be downloaded as a computer program which may be transferred from a remote computer (e.g., a server) to a requesting computer (e.g., a client) by way of data signals embodied in a carrier wave or other propagation medium via a communication link (e.g., a modem or network connection).

In the foregoing specification, the invention has been described with reference to specific exemplary embodiments thereof. It will, however, be evident that various modifications and changes may be made thereto without departing from the broader spirit and scope of the invention as set forth in the appended claims. The specification and drawings are, accordingly, to be regarded in an illustrative rather than a restrictive sense.

1. An apparatus, comprising:
a smart card comprising:
a) a connector to removably connect to an electronic system to be de-bugged;
b) at least one of the following:
a CPU complex to execute test software to de-bug the electronic system;
programmable hardware logic circuitry to perform test logic operations to de-bug the electronic system;
c) one or more communication interfaces to:
i) receive a download of customized test vectors for the electronic system from a network, the customized test vectors to be used by the test software and/or the programmable logic circuitry;
ii) communicate with a user interface device, the user interface device to control activity of the smart card.

2. The apparatus of claim 1 wherein the smart card comprises waveform generation circuitry, the waveform generation circuitry to drive input stimuli to the electronic system through the connector.

3. The apparatus of claim 2 wherein the smart card comprises a plurality of programmable voltage supply circuits coupled to the waveform generation circuitry, the waveform generation circuitry able to generate input stimuli for the electronic system having different logic voltage levels.

4. The apparatus of claim 1 wherein the smart card further comprises FIFO circuitry to keep digital state information of the electronic system.

5. The apparatus of claim 1 wherein the smart card further comprises analog-to-digital circuitry to generate digital samples of a signal's voltage waveform, the signal generated by the electronic system.

6. The apparatus of claim 5 wherein the smart card comprises a signal line that feeds into said analog-to-digital circuitry and feeds into digital circuitry that determines said signal's digital value.

7. The apparatus of claim 6 wherein the smart card is to identify a problem with the signal's digital value based on a comparison with a customized test vector and then compare digital samples of the signal taken by the analog-to-digital circuitry against a customized analog test vector for the signal.

8. The apparatus of claim 7 wherein the smart card is to report the problem and/or the digital samples of the signal along with the customized analog test vector to the user interface device.

9. An apparatus, comprising:
a de-bugging system comprising:
a) a smart card comprising:
i) a connector to removably connect to an electronic system to be de-bugged;
ii) at least one of the following:
a CPU complex to execute test software to de-bug the electronic system;
programmable hardware logic circuitry to perform test logic operations to de-bug the electronic system;
iii) one or more communication interfaces to receive customized test vectors for the electronic system that are to be used by the CPU complex and/or the programmable logic circuitry;
b) a cloud service comprising the customized test vectors, the customized test vectors to be downloaded to the smart card through the one or more communication interfaces.
c) a user interface device to communicate with the smart card through the one or more communication interfaces, the user interface device to control activity of the smart card.

10. The apparatus of claim 9 wherein the user interface device comprises a storage medium, the storage medium storing program code instructions of the user interface device, the program code instructions to cause the user interface device to perform any of the following:
connect to the smart card;
cause the customized test vectors to be downloaded from the cloud service to the smart card;
cause the test software to execute to test operation of the electronic system;
indicate whether a test of the electronic system has passed or failed.

11. The apparatus of claim 9 wherein the user interface device comprises a storage medium, the storage medium storing program code instructions of the user interface device, the program code instructions to cause the user interface device to perform any of the following:
receive digital samples of a voltage waveform of a signal of the electronic system from the smart card;
receive an analog test vector for the signal from the smart card;
display the digital samples against the analog test vector on the user interface device's display.

12. The apparatus of claim 9 wherein the test software includes generic software stored as firmware on the smart card.

13. The apparatus of claim 9 wherein the test software also includes a component of customized test software that is stored in the cloud service.

14. The apparatus of claim 9 wherein the smart card further comprises waveform generation circuitry, the waveform generation circuitry to drive input stimuli to the electronic system through the connector.

15. The apparatus of claim 9 wherein the smart card further comprises FIFO circuitry to keep digital state information of the electronic system.

16. The apparatus of claim 9 wherein the smart card further comprises analog-to-digital circuitry to generate digital samples of a signal's voltage waveform, the signal generated by the electronic system.

17. A method, comprising:
performing the following on a user interface device:
connecting to a smart card, the smart card connected to an electronic system to be de-bugged;
causing a cloud service to download customized test vectors for the electronic system to the smart card;
causing the smart card to begin execution of test software and/or operation of programmable hardware logic circuitry that uses the customized test vectors to test the electronic system.

18. The method of claim 17 further comprising the smart card detecting an error in operation of the electronic system and reporting the error to the user interface device.

19. The method of claim 17 further comprising the smart card capturing digital samples of a voltage waveform of a signal of the electronic system while also capturing the signal's digital values.

20. The method of claim 19 further comprising smart card detecting a problem in a digital value of the signal and then comparing the digital samples against an analog test vector of the signal.
